(19) United States
(12) Patent Application Publication
(10) Pub. No.: US 2005/0098106 A1
(43) Pub. Date: May 12, 2005

(54) Method and apparatus for improved electrode plate

(75) Inventors: Steven T. Fink, Mesa, AZ (US); Eric J. Strang, Chandler, AZ (US); Michael Landis, Gilbert, AZ (US)

Correspondence Address: PILLSBURY WINTHROP, LLP, P.O. BOX 10500, MCLEAN, VA, 22102, US

(73) Assignee: Tokyo Electron Limited, Tokyo (JP)

(21) Appl. No.: 10/705,225

(22) Filed: Nov. 12, 2003

(51) Int. Cl. C23C 16/00

(52) U.S. Cl. 118/715

(57) ABSTRACT

An electrode plate, configured to be coupled to an electrode in a plasma processing system, comprises a plurality of gas injection holes configured to receive gas injection devices. The electrode plate comprises three or more mounting holes, wherein the electrode plate is configured to be coupled with an electrode in the plasma processing system by aligning and coupling the three or more mounting holes with three or more mounting screws attached to the electrode.

### FIELD OF THE INVENTION

The present invention relates to a method and apparatus for utilizing an electrode plate in a plasma processing system and, more particularly, to an electrode plate assembly that facilitates improved maintenance of the plasma processing system.

### BACKGROUND OF THE INVENTION

The fabrication of integrated circuits (IC) in the semiconductor industry typically employs plasma to create and assist surface chemistry within a vacuum processing system necessary to remove material from and deposit material to a substrate. In general, plasma is formed within the processing system under vacuum conditions by heating electrons to energies sufficient to sustain ionizing collisions with a supplied process gas. Moreover, the heated electrons can have energy sufficient to sustain dissociative collisions and, therefore, a specific set of gases under predetermined conditions (e.g., chamber pressure, gas flow rate, etc.) are chosen to produce a population of charged species and chemically reactive species suitable to the particular process being performed within the system (e.g., etching processes where materials are removed from the substrate or deposition processes where materials are added to the substrate).

Although the formation of a population of charged species (ions, etc.) and chemically reactive species is necessary for performing the function of the plasma processing system (i.e. material etch, material deposition, etc.) at the substrate surface, other component surfaces on the interior of the processing chamber are exposed to the physically and chemically active plasma and, in time, can erode. The erosion of exposed components in the processing system can lead to a gradual degradation of the plasma processing performance and ultimately to complete failure of the system.

Therefore, in order to minimize the damage sustained by exposure to the processing plasma, a consumable or replaceable component, such as one fabricated from silicon, quartz, alumina, carbon, or silicon carbide, can be inserted within the processing chamber to protect the surfaces of more valuable components that would impose greater costs during frequent replacement and/or to affect changes in the process. Furthermore, it is desirable to select surface materials that minimize the introduction of unwanted contaminants, impurities, etc. to the processing plasma and possibly to the devices formed on the substrate. Often times, these consumables or replaceable components are considered part of the process kit, which is frequently maintained during system cleaning.

### SUMMARY OF THE INVENTION

A method and apparatus for utilizing an electrode plate in a plasma processing system is described.

According to one aspect, an electrode plate assembly for introducing process gas to a process space above a substrate in a plasma processing system comprises an electrode configured to be coupled to the plasma processing system, the electrode comprising three or more mounting screws fixedly coupled to the electrode. An electrode plate comprises a plurality of gas injection holes, and three or more mounting holes configured to be aligned with and coupled to the mounting screws in order to couple the electrode plate to the electrode. A plurality of gas injection devices are coupled to the plurality of gas injection holes, wherein the process gas passes through the plurality of gas injection devices into the process space.

According to another aspect, a disposable electrode plate for introducing process gas to a process space above a substrate in a plasma processing system comprises an electrode plate comprising a plurality of gas injection holes, and three or more mounting holes, wherein the electrode plate is configured to be coupled with an electrode by aligning and coupling the three or more mounting holes with three or more mounting screws fixedly attached to the electrode. A plurality of gas injection devices are coupled to the plurality of gas injection holes, wherein the process gas passes through the plurality of gas injection devices into the process space.

Additionally, a method of replacing an electrode plate for introducing process gas to a process space above a substrate in a plasma processing system comprises removing a first electrode plate from the plasma processing system and installing a second electrode plate in the plasma processing system. The first electrode plate and the second electrode plate each comprise a plurality of gas injection holes configured to receive gas injection devices, and three or more mounting holes, wherein each of the first electrode plate and the second electrode plate are configured to be coupled with an electrode in the plasma processing system by aligning and coupling the three or more mounting holes with three or more mounting screws fixedly attached to the electrode.

### BRIEF DESCRIPTION OF THE DRAWINGS

In the accompanying drawings:

FIG. 1 illustrates a schematic block diagram of a plasma processing system according to an embodiment of the present invention;

FIG. 2 presents a plan view of an electrode plate according to an embodiment of the present invention;

FIG. 3 presents cross-sectional view of the electrode plate depicted in FIG. 2;

FIG. 4 presents an expanded cross-sectional view of a gas injection hole in the electrode plate depicted in FIG. 2;

FIG. 5 presents an expanded view of a mounting hole coupled to the electrode plate depicted in FIG. 2;

FIG. 6 presents a plan view of an electrode according to an embodiment of the present invention;

FIG. 7 presents cross-sectional view of the electrode depicted in FIG. 6;

FIG. 8A illustrates a cross-sectional view of a first sealing device coupled to the electrode depicted in FIG. 6;

FIG. 8B illustrates a cross-sectional view of a second sealing device coupled to the electrode depicted in FIG. 6;

FIG. 9 illustrates a cross-sectional view of an electrical contact device coupled to the electrode depicted in FIG. 6;

FIG. 10 presents a top view of a gas injection device configured to be coupled to the electrode plate depicted in FIG. 2;

FIG. 11 presents a cross-sectional view of a gas injection device configured to be coupled to the electrode plate depicted in FIG. 2;

FIGS. 12A through 12D presents alternative gas injection devices configured to be coupled to the electrode plate depicted in FIG. 2;

FIG. 13 presents a side view of a mounting screw configured to be coupled to the electrode depicted in FIG. 6;

FIG. 14 presents a top view of the mounting screw depicted in FIG. 13; and

FIG. 15 presents a method of replacing an electrode plate for introducing process gas to a process space above a substrate in a plasma processing system.

### DETAILED DESCRIPTION OF SEVERAL EMBODIMENTS

In plasma processing, an electrode plate can, for example, be configured to be mounted on an upper surface of a processing chamber, and to be employed for distributing a process gas to a process space in the processing chamber. For conventional plasma processing systems, the electrode plate is electrically coupled to ground potential, and designed in a shower-head configuration having a plurality of gas injection orifices for uniform distribution of the process gas above a substrate.

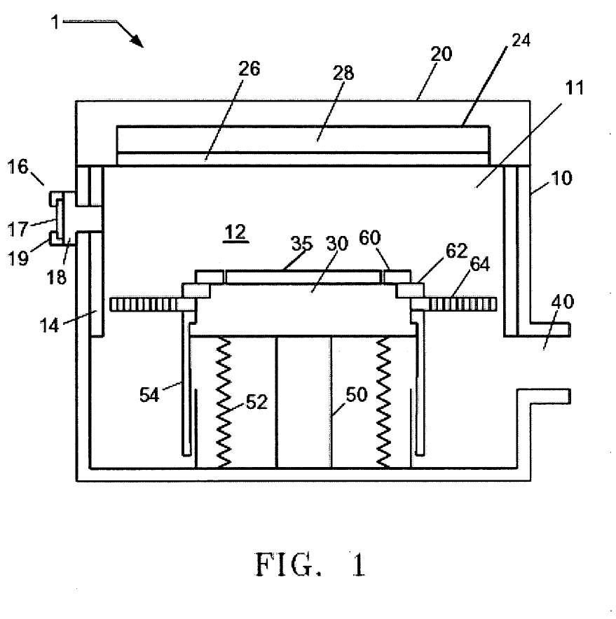

According to an embodiment of the present invention, a plasma processing system 1 is depicted in FIG. 1 comprising a plasma processing chamber 10, an upper assembly 20, an electrode plate assembly 24, a substrate holder 30 for supporting a substrate 35, and a pumping duct 40 coupled to a vacuum pump (not shown) for providing a reduced pressure atmosphere 11 in plasma processing chamber 10. Plasma processing chamber 10 can facilitate the formation of a processing plasma in process space 12 adjacent substrate 35. The plasma processing system 1 can be configured to process substrates of any size, such as 200 mm substrates, 300 mm substrates, or larger.

In the illustrated embodiment, electrode plate assembly 24 comprises an electrode plate 26 and an electrode 28 configured to be coupled to a gas injection assembly, and/or an upper electrode impedance match network. The electrode plate assembly 24 can be coupled to an RF source. In another alternate embodiment, the electrode plate assembly 24 is maintained at an electrical potential equivalent to that of the plasma processing chamber 10. For example, the plasma processing chamber 10, the upper assembly 20, and the electrode plate assembly 24 can be electrically connected to ground potential.

Plasma processing chamber 10 can further comprise an optical viewport 16 coupled to a deposition shield 14. Optical viewport 16 can comprise an optical window 17 coupled to the backside of an optical window deposition shield 18, and an optical window flange 19 can be configured to couple optical window 17 to the optical window deposition shield 18. Sealing members, such as O-rings, can be provided between the optical window flange 19 and the optical window 17, between the optical window 17 and the optical window deposition shield 18, and between the optical window deposition shield 18 and the plasma processing chamber 10. Optical viewport 16 can permit monitoring of optical emission from the processing plasma in process space 12.

Substrate holder 30 can further comprise a vertical translational device 50 surrounded by a bellows 52 coupled to the substrate holder 30 and the plasma processing chamber 10, and configured to seal the vertical translational device 50 from the reduced pressure atmosphere 11 in plasma processing chamber 10. Additionally, a bellows shield 54 can be coupled to the substrate holder 30 and configured to protect the bellows 52 from the processing plasma. Substrate holder 10 can further be coupled to at least one of a focus ring 60, and a shield ring 62. Furthermore, a baffle plate 64 can extend about a periphery of the substrate holder 30.

Substrate 35 can be transferred into and out of plasma processing chamber 10 through a slot valve (not shown) and chamber feed-through (not shown) via robotic substrate transfer system where it is received by substrate lift pins (not shown) housed within substrate holder 30 and mechanically translated by devices housed therein. Once substrate 35 is received from substrate transfer system, it is lowered to an upper surface of substrate holder 30.

Substrate 35 can be affixed to the substrate holder 30 via an electrostatic clamping system. Furthermore, substrate holder 30 can further include a cooling system including a re-circulating coolant flow that receives heat from substrate holder 30 and transfers heat to a heat exchanger system (not shown), or when heating, transfers heat from the heat exchanger system. Moreover, gas can be delivered to the back-side of substrate 35 via a backside gas system to improve the gas-gap thermal conductance between substrate 35 and substrate holder 30. Such a system can be utilized when temperature control of the substrate is required at elevated or reduced temperatures. In other embodiments, heating elements, such as resistive heating elements, or thermo-electric heaters/coolers can be included.

In the embodiment shown in FIG. 1, substrate holder 30 can comprise an electrode through which RF power is coupled to the processing plasma in process space 12. For example, substrate holder 30 can be electrically biased at a RF voltage via the transmission of RF power from a RF generator (not shown) through an impedance match network (not shown) to substrate holder 30. The RF bias can serve to heat electrons to form and maintain plasma. In this configuration, the system can operate as a reactive ion etch (RIE) reactor, wherein the chamber and upper gas injection electrode serve as ground surfaces. A typical frequency for the RF bias can range from about 1 MHz to about 100 MHz, or can be about 13.56 MHz. RF systems for plasma processing are well known to those skilled in the art.

Alternately, the processing plasma in process space 12 can be formed using a parallel-plate, capacitively coupled plasma (CCP) source, an inductively coupled plasma (ICP) source, any combination thereof, and with and without magnet systems. Alternately, the processing plasma in process space 12 can be formed using electron cyclotron resonance (ECR). In yet another embodiment, the processing plasma in process space 12 is formed from the launching of a Helicon wave. In yet another embodiment, the processing plasma in process space 12 is formed from a propagating surface wave.

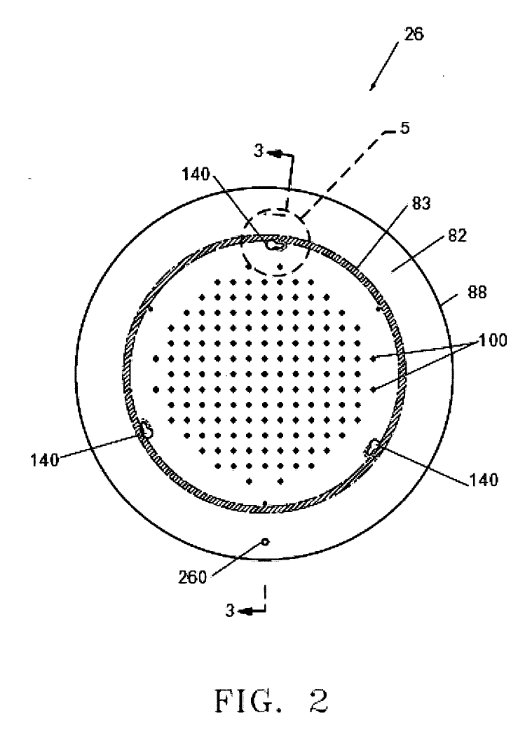

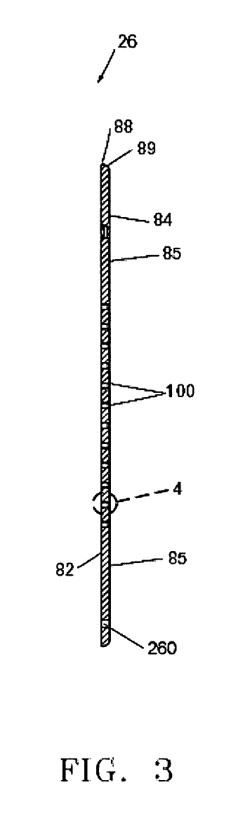

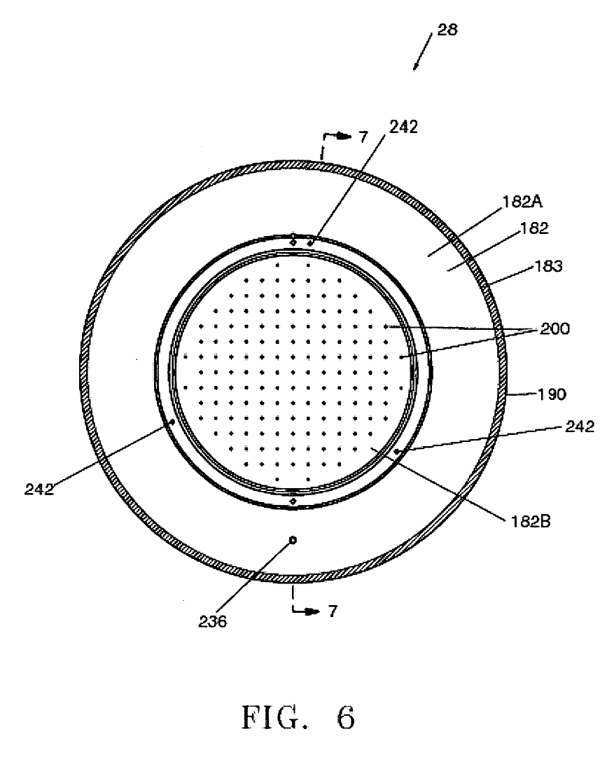

Referring now to an illustrated embodiment of the present invention, the electrode plate assembly 24 comprises an electrode plate 26, depicted in FIG. 2 (top plan view) and FIG. 3 (cross sectional view), configured to be coupled to an electrode 28, depicted in FIG. 6 (top plan view) and FIG. 7 (cross sectional view). The electrode plate 26 comprises a first surface 82 having a coupling surface 83 for coupling the electrode plate 26 to the electrode 28, a second surface 84 comprising a plasma surface 85 configured to face the processing plasma in the plasma processing chamber 10 (see FIG. 1), and a peripheral edge 88. As shown in FIG. 3, the peripheral edge 88 can, for example, further comprise a rounded edge 89.

With continuing reference to FIG. 2 and FIG. 3, and as shown in FIG. 10 and FIG. 11, the electrode plate 26 further includes one or more gas holes 100 extending between the first surface 82 and the second surface 88, wherein each gas injection hole 100 (see FIG. 4) is configured to receive a replaceable gas injection device 110, depicted in FIGS. 10 and 11. Each gas injection hole 100 comprises a plug receiving region 102, a shoulder capturing region 104 coupled to the plug receiving region 102, and a tip receiving region 106 coupled to the shoulder capturing region 104. Referring now to FIG. 10 and FIG. 11, each replaceable gas injection device 110 comprises a plug region 112, a shoulder region 114 coupled to the plug region 112, and a tip region 116 coupled to the shoulder region 114, wherein each gas injection device 110 is configured to be inserted into each gas injection hole 100 such that the plug receiving region 102 receives the plug region 112, the tip receiving region 106 receives the tip region 116, and the shoulder capturing region 104 captures the shoulder region 114 of the gas injection device 110.

Referring still to FIG. 10 and FIG. 11, each gas injection device 110 comprises a gas injection orifice 120 having an entrant region 122 for receiving a processing gas and an exit region 124 for coupling the processing gas to the plasma processing chamber 10, the exit region 124 comprising an injection surface 126 contiguous with the plasma surface 85. The processing gas can, for example, comprise a mixture of gases such as argon, CF₄ and O₂, or argon, C₄F₈ and O₂ for oxide etch applications, or other chemistries such as, for example, O₂/CO/Ar/C₄F₈, O₂/Ar/C₄F₈, O₂/CO/AR/C₅F₈, O₂/CO/Ar/C₄F₆, O₂/Ar/C₄F₆, N₂/H₂, N₂/O₂.

The number of gas injection holes 100 formed within electrode plate 26 can range from about 1 to about 10,000. Alternatively, the number of gas injection orifices 100 can range from about 50 to about 500; or the number of gas injection orifices 100 can be at least about 100. Furthermore, a diameter of the gas injection orifice 120 can range from about 0.1 to about 20 mm. Alternatively, the diameter can range from about 0.5 to about 5 mm, or from about 0.5 to about 2 mm. In addition, a length of a gas injection orifice can range from about 0.5 to about 20 mm. Alternatively, the length can range from about 2 to about 15 mm, or from about 3 to about 12 mm.

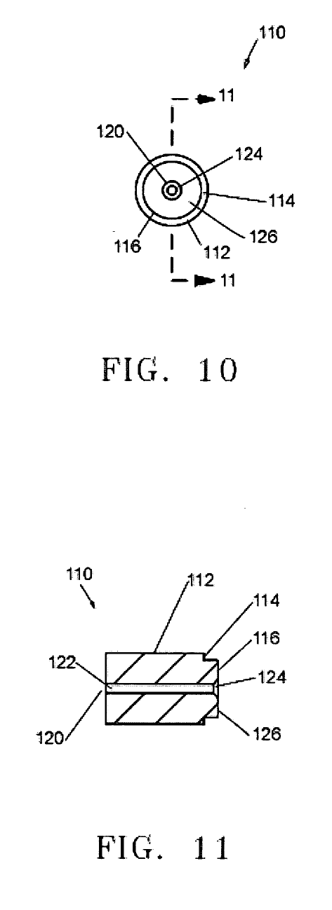

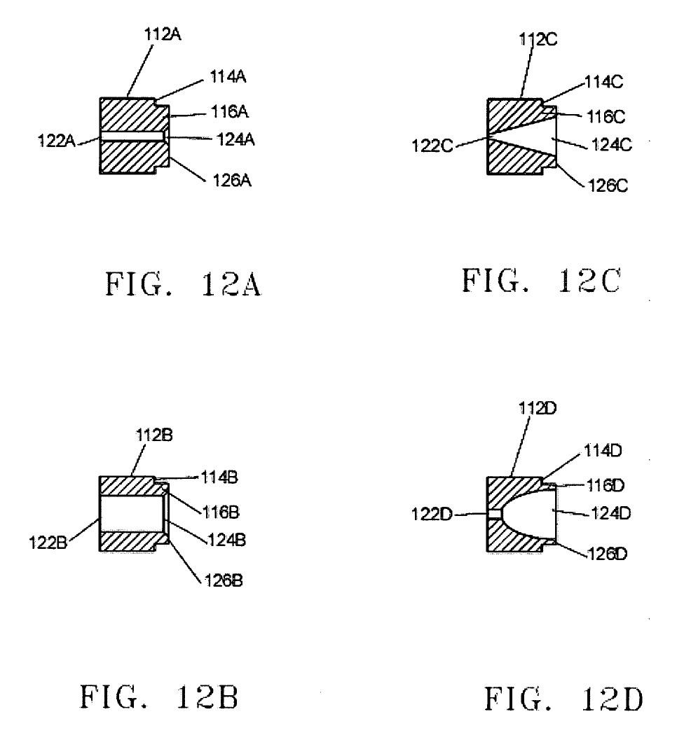

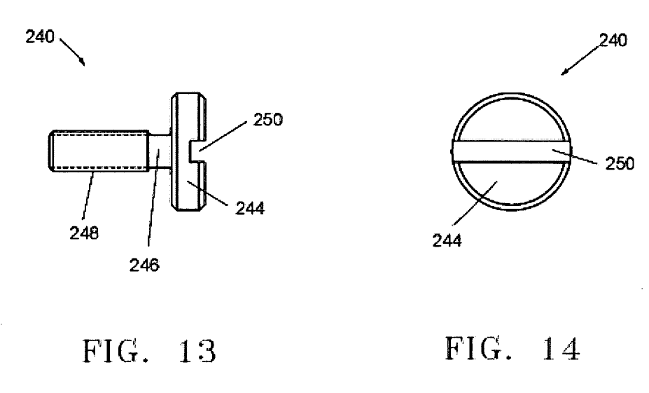

As described above, the diameter and the length of the gas injection orifice can be varied. For example, FIG. 12A provides an illustration of a gas injection device with a gas injection orifice having a shorter length relative to that shown in FIG. 10, and FIG. 12B provides an illustration of a gas injection device with a gas injection orifice having a larger diameter relative to that shown in FIG. 10. Alternatively, the gas injection orifice can comprise a divergent nozzle, such as a conical divergent nozzle as illustrated in FIG. 12C, or a minimum-length or perfect nozzle as illustrated in FIG. 12D; the latter of which are understood to those skilled in the art of nozzle design in compressible gas dynamics. Alternatively, the gas injection orifice can comprise a convergent nozzle, such as a conical convergent nozzle.

Additionally, the insertion of gas injection devices 110 into the gas injection holes 100 of electrode plate 26 can be performed in such a manner to facilitate a distribution of at least one of orifice diameter, orifice length, and orifice shape across the plasma surface 85 of electrode plate 26. For example, gas injection devices 110 having at least one of an increased diameter, or decreased length can be distributed towards the center of electrode plate 26 in order to increase the flow of process gas to the center of process space 11 relative to the flow of process gas to the edge of process space 11. Alternatively, gas injection devices 110 having at least one of a decreased diameter, or increased length can be distributed towards the center of electrode plate 26 in order to decrease the flow of process gas to the center of process space 11 relative to the flow of process gas to the edge of process space 11.

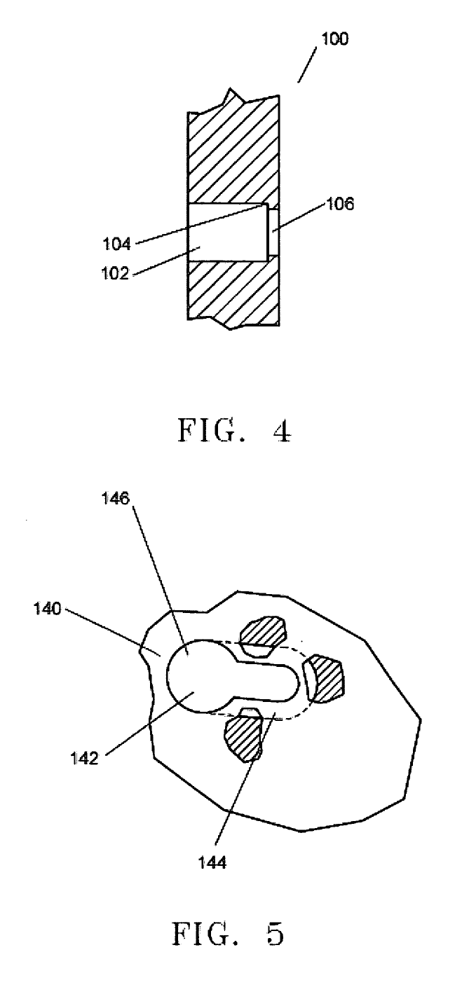

Referring still to FIG. 2 and FIG. 3, the electrode plate 26 further comprises three or more attachment devices 140 that can facilitate coupling the electrode plate 26 to the electrode 28. As shown in FIG. 5, each attachment device 140 comprises a recess slot 142, and a recess lip 144 extending over a portion of the top of each recess slot 142 in order to retain an attachment screw upon rotation of the electrode plate 26. Since the recess lip 144 extends only over a portion of recess slot 142, an insertion opening 146 is provided for coupling the attachment screw to the recess slot 142.

The electrode plate 26 can be fabricated from at least one of aluminum, coated aluminum, silicon, quartz, silicon carbide, silicon nitride, carbon, alumina, sapphire, Teflon, and polyimide. The electrode plate 26 can, for example, be fabricated using at least one of machining, laser-cutting, grinding, and polishing.

For coated aluminum, the coating can facilitate the provision of an erosion resistant surface when the electrode plate 26 is exposed to harsh processing environments, such as plasma. During fabrication, providing a coating can comprise at least one of providing a surface anodization on one or more surfaces, providing a spray coating on one or more surfaces, or subjecting one or more surfaces to plasma electrolytic oxidation. The coating can comprise at least one of a III-column element and a Lanthanon element. The coating can comprise at least one of Al₂O₃, Yttria (Y₂O₃), Sc₂O₃, Sc₂F₃, YF₃, La₂O₃, CeO₂, Eu₂O₃, and DyO₃. Methods of anodizing aluminum components and applying spray coatings are well known to those skilled in the art of surface material treatment.

All surfaces on electrode plate 26 can be coated, using any of the techniques described above. In another example, all surfaces on electrode plate 26, except for a contact region 83 on second surface 84 as shown in FIG. 2 (cross-hatched region) can be coated, using any of the techniques described above. Prior to the application of the coating to the surfaces of the electrode plate 26, the contact region 83 can be masked in order to prevent the formation of the coating thereon. Alternatively, following the application of the coating to the surfaces of the electrode plate 26, the contact region 83 can be machined to remove the coating formed thereon.

Additionally, each gas injection device 110 can be fabricated from at least one of aluminum, coated aluminum, silicon, quartz, silicon carbide, silicon nitride, carbon, alumina, sapphire, Teflon, and polyimide. For coated aluminum, the coating can facilitate the provision of an erosion resistant surface when the electrode plate 26 is exposed to harsh processing environments, such as plasma. During fabrication, providing a coating can comprise at least one of providing a surface anodization on one or more surfaces, providing a spray coating on one or more surfaces, or subjecting one or more surfaces to plasma electrolytic oxidation. The coating can comprise at least one of a III-column element and a Lanthanon element. The coating can comprise at least one of Al₂O₃, Yttria (Y₂O₃), Sc₂O₃, Sc₂F₃, YF₃, La₂O₃, CeO₂, Eu₂O₃, and DyO₃. Methods of anodizing aluminum components and applying spray coatings are well known to those skilled in the art of surface material treatment. Each gas injection device 110 can, for example, be fabricated using at least one of machining, laser-cutting, grinding, and polishing.

Referring now to FIG. 6 and FIG. 7, a plan view of electrode 28 and a cross-sectional view of electrode 28 are shown, respectively. Electrode 28 comprises a rear surface 182 having a coupling surface 182A for coupling the electrode 28 to the upper assembly 20, a front surface 184 comprising a first mating surface 185 configured to couple with electrode plate 26, and a second mating surface 195 configured to couple the electrode 28 with the processing chamber 10, and an outer radial edge 190. With continuing reference to FIG. 6 and FIG. 7, the electrode 28 further includes one or more gas injection mating holes 200 extending between a plenum surface 182B and the front surface 184, wherein each gas injection mating hole 200 is configured to align with each gas injection hole 100 when the electrode plate 26 is coupled to the electrode 28. The plenum surface 182B can be recessed from the contact surface 182A in order to form a plenum.

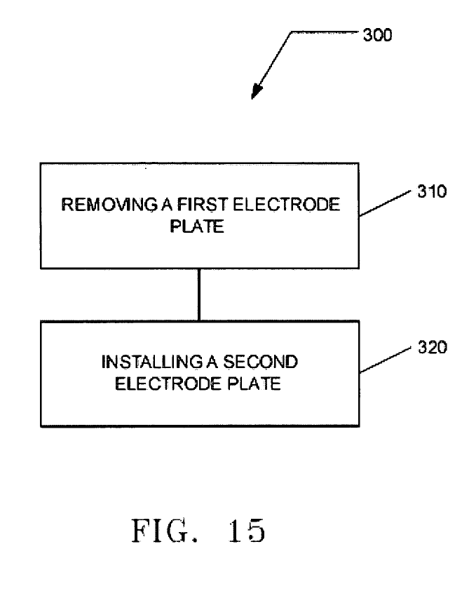

Additionally, referring to FIG. 13, FIG. 14, and FIG. 6, the electrode 28 comprises three or more attachment features that facilitate coupling the electrode plate 26 to the electrode 28. Each attachment feature comprises mounting screw 240, as shown in FIG. 12 (side view) and FIG. 13 (top view), configured to be coupled to a mounting hole 242 on electrode 28. Each mounting screw 240 can comprise a head region 244 having a tool mating feature 250 for adjusting the mounting screw 240 in the mounting hole 242, a shaft region 246 coupled to the head region 244, and a threaded end 248 coupled to the shaft region 246. Each mounting hole 242 can comprise a tapped region in order to receive the threaded end 248 of mounting screw 240. Each mounting hole 242 can optionally include a locking helicoil in order to secure each mounting screw 240, and maintain the position of the head region 244 relative to the front surface 184 of the electrode 28. Initial adjustment of each mounting screw 240 in each mounting hole 242 can determine the extent to which the electrode plate 26 is coupled to the electrode 28. Once the three or more mounting screws 240 are coupled to the electrode 28, the electrode 28 is configured to receive the electrode plate 26 by aligning each head region 244 of each mounting screw 240 with the insertion opening 146 of each recess slot 142 on the electrode plate 26, and rotating the electrode plate 26 counter-clockwise, as shown in FIG. 2 (or, alternatively, clockwise), until the recess lip 144 of each recess slot 142 captures the head region 244 of each mounting screw 240.

The electrode 28 can be fabricated from at least one of aluminum, coated aluminum, silicon, quartz, silicon carbide, silicon nitride, carbon, alumina, sapphire, Teflon, and polyimide. The electrode 28 can be fabricated using at least one of machining, laser-cutting, grinding, and polishing.

For coated aluminum, the coating can facilitate the provision of an erosion resistant surface when the electrode 28 is exposed to harsh processing environments, such as plasma. During fabrication, providing a coating can comprise at least one of providing a surface anodization on one or more surfaces, providing a spray coating on one or more surfaces, or subjecting one or more surfaces to plasma electrolytic oxidation. The spray coating can comprise at least one of Al₂O₃, Yttria (Y₂O₃), Sc₂O₃, Sc₂F₃, YF₃, La₂O₃, CeO₂, Eu₂O₃, and DyO₃. The coating can comprise at least one of a III-column element and a Lanthanon element. Methods of anodizing aluminum components and applying spray coatings are well known to those skilled in the art of surface material treatment.

All surfaces on electrode 28 can be coated using any of the techniques described above. In another example, all surfaces on electrode 28, except for a contact region 183 on the rear surface 182 as shown in FIG. 6 (cross-hatched region) can be coated using any of the techniques described above. Prior to the application of the coating to the surfaces of the electrode 28, the contact region 183 can be masked in order to prevent the formation of the coating thereon. Alternatively, following the application of the coating to the surfaces of the electrode 28, the contact region 183 can be machined to remove the coating formed thereon.

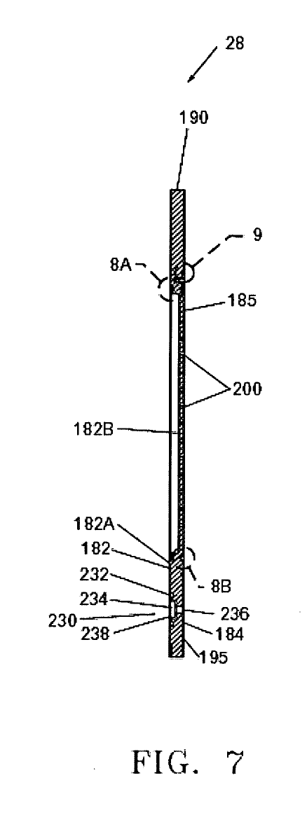

In order to provide a vacuum seal between the electrode 28 and the upper assembly 20, the electrode 28 can further comprise a first sealing groove 210, having a dovetail cross-section or rectangular cross-section, on the rear surface 182, as shown in FIG. 8A, configured to receive an elastomer O-ring. Additionally, in order to provide a vacuum seal between the electrode plate 26 and the electrode 28, the electrode 28 can further comprise a second sealing groove 212, having a dovetail cross-section or rectangular cross-section, on the front surface 184, as shown in FIG. 8B, configured to receive an elastomer O-ring. When the electrode 28 is fabricated from coated aluminum, the coating is removed from, or prevented from forming on, the interior of the first sealing groove 210 and the second sealing groove 212.

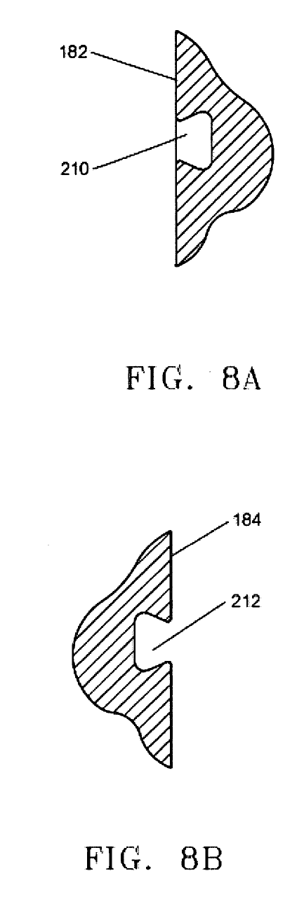

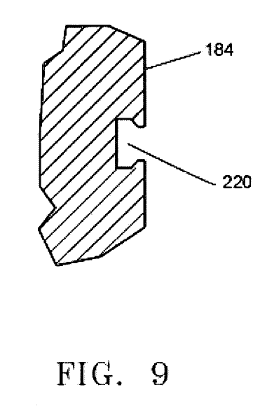

Additionally, electrode 28 can further comprise an electrical contact feature, wherein the electrical contact feature comprises, for example, an electrical contact groove 220, as shown in FIG. 9, configured to receive a deformable electrical contact device such as Spirashield™. When the electrode plate 26 is mechanically fastened to the electrode 28, the Spirashield™ (having an inner elastomeric core surrounded by a helical metal shield) is compressed within electrical contact groove 220, hence, improving the electrical contact between, for example, the contact region 83 on the electrode plate 26 and the electrode 28. When the electrode 28 is fabricated from coated aluminum, the coating is removed from, or prevented from forming on, the interior of the electrical contact groove 220.

Furthermore, the electrode 28 can further comprise a diagnostics port 230, and a third sealing feature 232 coupled to the coupling surface 182A of the electrode 28 and configured to seal the diagnostics port 230 with the upper assembly 20. As depicted in FIG. 7, the diagnostics port 230 can include an entrant cavity 234 and an exit through-hole 236 comprising an interior surface 238. Similarly, the third sealing feature 232 can, for example, comprise a dovetail cross-section or rectangular cross-section configured for receiving an elastomer O-ring. The diagnostics port 230 can be used to couple a diagnostics system (not shown) with the process space 11 of plasma processing chamber 10. For example, the diagnostics system can comprise a pressure manometer. Additionally, once the electrode plate 26 is coupled to the electrode 28, a second exit through-hole 260 on the electrode plate 26 is configured to align with the exit through-hole 236 on the electrode 28.

Referring now to FIG. 15, a method for replacing a electrode plate from an electrode mounted adjacent a process space above a substrate in a plasma processing system is described. The method comprises a flow chart 300 beginning in 310 with removing a first electrode plate from the plasma processing system, wherein the electrode plate comprises a plurality of gas injection holes for receiving a plurality of gas injection devices through which process gas is introduced to the process space of the plasma processing system. Removing the first electrode plate can, for example, comprise venting the plasma processing system to atmospheric conditions and opening the plasma processing chamber to access the interior, followed by decoupling the electrode plate from the electrode. Decoupling the electrode plate from the electrode can, for example, comprise rotating the electrode plate relative to the electrode in order to disengage the mounting screws from the recess slots on the electrode plate.

In 320, a second electrode plate is installed in the plasma processing system by coupling the second electrode plate to the substrate holder. The second electrode plate can comprise the first electrode plate following refurbishing, or it can be a newly fabricated electrode plate having a plurality of gas injection holes for receiving a plurality of gas injection devices. The refurbishing can include replacing the gas injection devices in the gas injection holes of the first electrode plate. The second electrode plate is coupled to the electrode by aligning each head region of each mounting screw with the insertion opening of each recess slot on the second electrode plate, and rotating the second electrode plate counter-clockwise, as shown in FIG. 2 (or, alternatively, clockwise), until the recess lip of each recess slot captures the head region of each mounting screw.

Although only certain exemplary embodiments of this invention have been described in detail above, those skilled in the art will readily appreciate that many modifications are possible in the exemplary embodiments without materially departing from the novel teachings and advantages of this invention. Accordingly, all such modifications are intended to be included within the scope of this invention.

1. An electrode plate assembly for introducing process gas to a process space above a substrate in a plasma processing system comprising:
an electrode configured to be coupled to said plasma processing system;
three or more mounting screws coupled to said electrode;
an electrode plate comprising a plurality of gas injection holes, and three or more mounting holes configured to be aligned with and coupled to said mounting screws in order to couple said electrode plate to said electrode; and
a plurality of gas injection devices coupled to said plurality of gas injection holes, wherein said process gas passes through said plurality of gas injection devices into said process space.

2. The electrode plate assembly of claim 1, wherein each of said gas injection devices comprises a gas injection orifice.

3. The electrode plate assembly of claim 2, wherein each of said gas injection orifices is characterized by a diameter, a shape, and a length.

4. The electrode plate assembly of claim 3, wherein at least one of said diameter, shape, and length is varied for at least one gas injection orifice as compared to another of said gas injection orifices.

5. The electrode plate assembly of claim 4, wherein said variation facilitates an increase in the flow rate of said process gas to the center of said process space above said substrate relative to the flow of process gas to the edge of said process space.

6. The electrode plate assembly of claim 4, wherein said variation facilitates a decrease in the flow rate of said process gas to the center of said process space above said substrate relative to the flow of process gas to the edge of said process space.

7. The electrode plate assembly of claim 1, wherein said electrode plate is made from at least one of aluminum, coated aluminum, silicon, quartz, silicon carbide, silicon nitride, carbon, alumina, sapphire, polyimide, and Teflon.

8. The electrode plate assembly of claim 1, wherein said plurality of gas injection devices is made from at least one of aluminum, coated aluminum, silicon, quartz, silicon carbide, silicon nitride, carbon, alumina, sapphire, polyimide, and Teflon.

9. The electrode plate assembly of claim 1, wherein said electrode is made from at least one of aluminum, coated aluminum, silicon, quartz, silicon carbide, silicon nitride, carbon, alumina, sapphire, polyimide, and Teflon.

10. The electrode plate assembly of claim 1, wherein each of said three or more mounting screws comprise a head region, and each of said three or more mounting holes comprise a slot recess having an insertion opening configured to pass said head region when aligning said electrode plate with said electrode and a recess lip configured to capture said head region when coupling said electrode plate to said electrode.

11. The electrode plate assembly of claim 7, wherein said electrode plate is made from said coated aluminum and the coating comprises at least one of surface anodization, a coating formed using plasma electrolytic oxidation, and a spray coating.

12. The electrode plate assembly of claim 8, wherein said plurality of gas injection devises are made from said coated aluminum and the coating comprises at least one of surface anodization, a coating formed using plasma electrolytic oxidation, and a spray coating.

13. The electrode plate assembly of claim 9, wherein said electrode is made from said coated aluminum and the coating comprises at least one of surface anodization, a coating formed using plasma electrolytic oxidation, and a spray coating.

14. The electrode plate assembly of claim 7, wherein said electrode plate is made from coated aluminum and the coating comprises at least one of a III-column element and a Lanthanon element.

15. The electrode plate assembly of claim 8, wherein said plurality of gas injection devices are made from coated aluminum and the coating comprises at least one of a III-column element and a Lanthanon element.

16. The electrode plate assembly of claim 9, wherein said electrode is made from coated aluminum and the coating comprises at least one of a III-column element and a Lanthanon element.

17. The electrode plate assembly of claim 7, wherein said electrode plate is made from coated aluminum and the coating comprises at least one of Al₂O₃, Yttria (Y₂O₃), Sc₂O₃, Sc₂F₃, YF₃, La₂O₃, CeO₂, Eu₂O₃, and DyO₃.

18. The electrode plate assembly of claim 8, wherein said plurality of gas injection devices are made from coated aluminum and the coating comprises at least one of Al₂O₃, Yttria (Y₂O₃), Sc₂O₃, Sc₂F₃, YF₃, La₂O₃, CeO₂, Eu₂O₃, and DyO₃.

19. The electrode plate assembly of claim 9, wherein said electrode is made from coated aluminum and the coating comprises at least one of Al₂O₃, Yttria (Y₂O₃), Sc₂O₃, Sc₂F₃, YF₃, La₂O₃, CeO₂, Eu₂O₃, and DyO₃.

20. A disposable electrode plate for introducing process gas to a process space above a substrate in a plasma processing system comprising:
an electrode plate comprising a plurality of gas injection holes, and three or more mounting holes, wherein said electrode plate is configured to be coupled with an electrode by aligning and coupling said three or more mounting holes with three or more mounting screws attached to said electrode; and
a plurality of gas injection devices coupled to said plurality of gas injection holes, wherein said process gas passes through said plurality of gas injection devices into said process space.

21. A method of replacing an electrode plate for introducing process gas to a process space above a substrate in a plasma processing system comprising:
removing a first electrode plate from said plasma processing system; and
installing a second electrode plate in said plasma processing system,
wherein said first electrode plate and said second electrode plate each comprise a plurality of gas injection holes configured to receive gas injection devices, and three or more mounting holes, wherein each of said first electrode plate and said second electrode plate are configured to be coupled with an electrode in said plasma processing system by aligning and coupling said three or more mounting holes with three or more mounting screws attached to said electrode.

22. The method of claim 21, further comprising:
replacing said gas injection devices in said gas injection holes of said first electrode plate to create said second electrode plate.

23. The method of claims 21, wherein each of said three or more mounting screws comprise a head region, and each of said three or more mounting holes comprise a slot recess having an insertion opening configured to pass said head region when aligning said electrode plate with said electrode and a recess lip configured to capture said head region when coupling said electrode plate to said electrode, and said installing comprises rotating said second electrode plate relative to said electrode.
